(19) United States
(12) Patent Application Publication
(10) Pub. No.: US 2016/0177182 A1
(43) Pub. Date: Jun. 23, 2016

(54) FIRE-RESISTANT PRINTED CIRCUIT BOARD ASSEMBLIES

(71) Applicant: EMPIRE TECHNOLOGY DEVELOPMENT LLC, Wilmington, DE (US)

(72) Inventors: William Brenden CARLSON, Seattle, WA (US); Gregory D. PHELAN, Cortland, NY (US)

(73) Assignee: EMPIRE TECHNOLOGY DEVELOPMENT LLC, Wilmington, DE (US)

(21) Appl. No.: 14/909,419

(22) PCT Filed: Jul. 31, 2013
(86) PCT No.: PCT/US2013/052840

§ 371 Date: Feb. 1, 2016

(51) Int. Cl. C09K 21/14; H05K 1/02; C08B 37/00; H05K 1/03; C08B 15/00; C08B 31/00

(52) U.S. Cl. CPC C09K 21/14; C08B 15/005; C08B 31/003; C08B 37/0045; H05K 1/0353; H05K 1/0201; H05K 2201/012

(57) ABSTRACT

Printed circuit boards, or PCBs, may include cross-linked oligomers that have been modified to prevent corrosion and have reduced flammability. The oligomers may be functionalized to include cross-linkable moieties and a flame retardant. The modified materials are more environmentally benign and less toxic than current fiberglass technologies used to manufacture PCBs.

### BACKGROUND

A printed circuit board, or PCB, is typically a thin flat board made of fiberglass or other similar non-conductive material, onto which electrically conductive wires or traces are printed or etched. Electronic components, such as integrated circuits, resistors, capacitors, diodes, electronic filters, microcontrollers, relays, and so on, may be mounted on the board, and the traces connect the components together to form a working circuit or assembly. A PCB may have conductors on one side or both sides, and may be multi-layered, having many layers of conductors, each separated by insulating layers. While most PCBs are flat and rigid, flexible substrates may also be used. Some examples of PCBs include computer motherboards, memory chips, and network interface cards.

Historically, durable electronic goods such as televisions, radios, and stereos would take five to twenty years to enter the waste stream. Today, items with logic, memory, and complex PCBs may enter the waste stream more rapidly. In many countries, a three-year-old cell phone, portable music player, or gaming console is considered out of date, and may be disposed of. Thus, an unintended consequence of the information technology revolution is new and unusually toxic waste. Estimates suggest that 100 million computers are discarded worldwide every year. In the United States this amounts to about two million tons of computer-related waste per year and climbing. The European Union has identified waste electrical and electronic equipment (WEEE) as the fastest growing waste stream, amounting to about 5% of the municipal solid waste (MSW) and growing at three times the rate of the total MSW stream.

Normal waste that enters the MSW stream usually consists of simple materials with a limited number of disposal steps. Electronic waste management is much more complex. WEEE contains mainly useful materials, such as recyclable metals, glasses, and plastics, and also valuable metals, such as Au, Cu, Ni, rare earths, Ru, Pd, Ag, and Zn. Because of these characteristics, WEEE is particularly attractive to reclamation and recycling processes. However, WEEE often contains toxic metals such as Pb, Hg, Cr, Cd and toxic organic and inorganic compounds, which makes these processes potentially hazardous. Safe and efficient separation of WEEE components is an ongoing technical challenge.

Electronic components may also pose a fire risk. Electromigration in PCBs makes short circuits possible. Because of this potential for fire, fire-suppressant materials, such as brominated bisphenol-A (brominated-BPA) epoxy resins have been used in circuit boards to reduce fire events. However, these resins may not be able to sustain suppressing of combustion throughout a duration of the fire event. Brominated BPA also can behave as an endocrine toxin and releases toxic chemicals when pyrolyzed or decomposed. In addition, because of the sensitive nature of components such as chips and diodes on a PCB, material selection in PCBs must also take into account whether the materials used can cause corrosion to the electronic components.

Therefore, there remains a need for reducing potential hazards presented by PCBs.

### SUMMARY

Printed circuit boards, or PCBs, may be produced to include cross-linked oligomers that have been modified to prevent corrosion and have reduced flammability. The modified materials are more environmentally benign and less toxic than current fiberglass technologies used to manufacture PCBs. While initially hydrophobic, these materials are able to be processed in the waste stream by techniques that include water processing of electronic waste to break down the PCBs and recover the materials to manufacture next-generation electronic components.

In an embodiment, a printed circuit board assembly includes at least one substrate sheet comprising a flame resistant material, electrical conduction traces disposed on the substrate sheet, and electronic components disposed on the substrate sheet in contact with the electrical conduction traces. The flame resistant material includes functionalized oligosaccharides comprising cross-linked oligosaccharides functionalized with a flame retardant.

In an embodiment, a flame resistant material includes functionalized oligosaccharides comprising cross-linked oligosaccharides functionalized with a flame retardant.

In an embodiment, a kit for producing a flame resistant material includes functionalized oligosaccharides comprising oligosaccharides functionalized with a flame retardant, and the functionalized oligosaccharides having cross-linkable moieties configured to be cross-linkable with cross-linkable moieties of at least one other of the functionalized oligosaccharides. The kit may also include at least one cross-linking agent for cross-linking the cross-linkable moieties.

In an embodiment, a method for producing a flame resistant includes functionalizing oligosaccharides with cross-linkable moieties and a flame retardant, and cross-linking the functionalized oligosaccharides.

### BRIEF DESCRIPTION OF THE FIGURES

FIG. 1 depicts a printed circuit board and method steps for producing the printed circuit board according to an embodiment.

FIGS. 2A-2C depict simplified illustrations of polysaccharides according to an embodiment.

FIG. 3 shows a representative process for producing a cross-linked, fire-resistant oligosaccharide material according to an embodiment.

FIGS. 4A-4D show representative process steps for producing boronated, epoxy-cellulose according to an embodiment.

FIG. 5 depicts a direct cross-linking of boronated vinyl cellulose according to an embodiment.

### DETAILED DESCRIPTION

Non-toxic and environmentally benign circuit boards for the electronics industry may be produced by using often naturally occurring saccharides as a flame retardant material in the circuit boards. The saccharides provide for a reduction in pollution and a reduction in the release of highly toxic materials from the disposal of electronic waste.

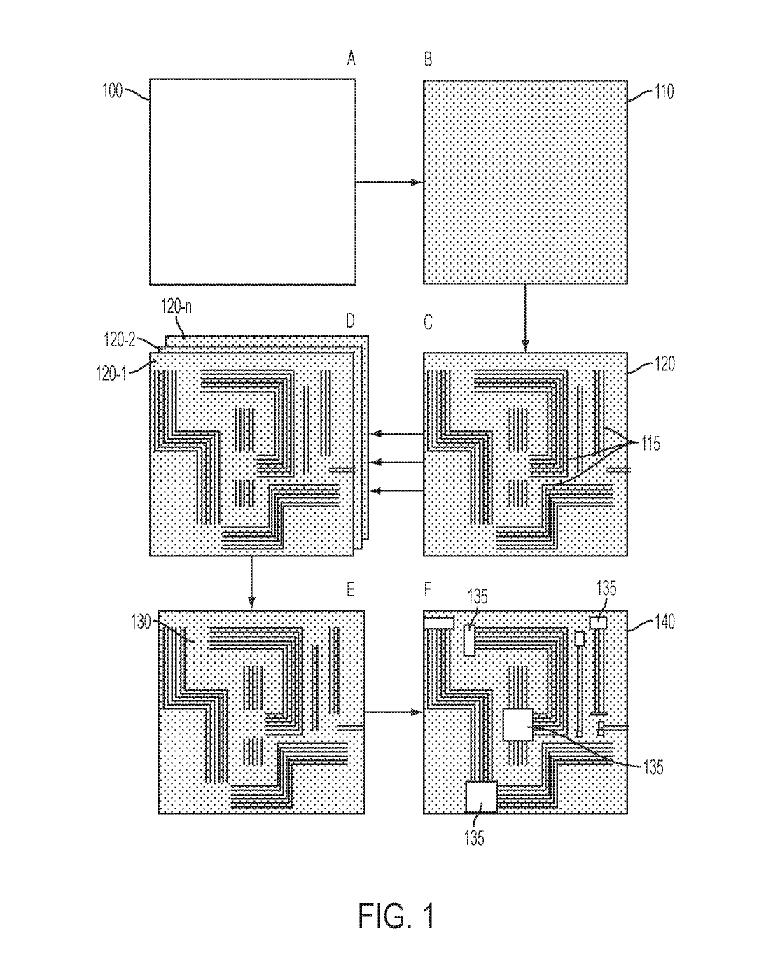

In an embodiment, a printed circuit board 140 (as represented in FIG. 1, panel F, discussed in more detail below) may be formed of a substrate sheet 100 that includes a flame resistant material to reduce the risk of fires originating from the circuit board. The flame resistant material may include cross-linked oligosaccharides that are functionalized with a flame retardant. The circuit board 140 may also have any of a variety of electrical conduction traces 115 (as represented in FIG. 1, panel C) disposed on the substrate sheet, as well as any of a variety of electronic components 135 (as represented in FIG. 1, panel F) disposed on the substrate sheet in contact with the electrical conduction traces.

The conductive traces 115, that may be copper for example, may be formed by etching, wherein an entire surface is covered with the conductive material, the surface is masked to cover areas of the conductive material that are to remain, and the unmasked portions of the conductive material are removed. Conductive traces may also be directly deposited by methods such as printing. The electronic components 135 may be any of microprocessors, diodes, microcontrollers, integrated circuits, logic devices, resistors, capacitors, electronic filters, microcontrollers, and so on.

The substrate sheet may be a laminate material, that may be one or more layers of cloth and a resin material. Varying cloth weaves (threads per cm), cloth thicknesses, and resin percentages may be configured to achieve a desired final thickness and dielectric characteristics. The cloth or fiber material used, resin material, and the cloth to resin ratio may be configured to determine the characteristics of the laminate produced. Some characteristics that may be considered include, but are not limited to, the level to which the laminate is fire retardant, the dielectric constant, the loss factor, the tensile strength, the shear strength, the glass transition temperature, and the Z-axis expansion coefficient (how much the thickness changes with temperature). The substrate sheets may be fibrous papers, and may include papers made from cotton fibers, wood fibers, linen fibers, grass fibers, and so on. In an embodiment, cotton fiber sheets may be used as the substrate sheet.

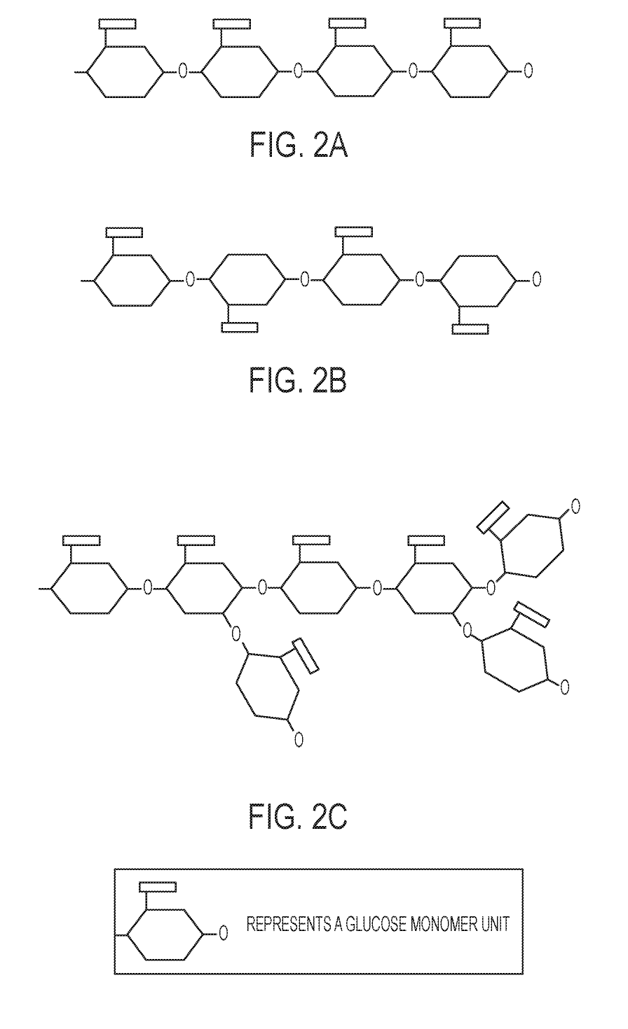

The substrate sheets may be infused or coated with a flame resistant material or resin. Polysaccharides may be used as a material for producing the resin. Polysaccharides are long carbohydrate molecules of monosaccharide units joined together by glycosidic bonds, and range in structure from linear to highly branched. Polysaccharides have a general formula of (C₆H₁₀O₅)ₙ where 40≦n≦3000. Some examples of polysaccharides include, but are not limited to, pectin, cellulose, hemi-cellulose, starch, glycogen, amylose and chitin. Representative structures of starch, cellulose and glycogen, all based on the glucose monomer unit, are depicted in FIGS. 2A-2C respectively. Starch (FIG. 2A) is a naturally abundant nutrient carbohydrate found chiefly in the seeds, fruits, tubers, roots, and stem pith of plants. Cellulose (FIG. 2B) is a naturally occurring polymer of glucose that is the principal component of trees and other vegetation. Glycogen (FIG. 2C) is a multi-branched polysaccharide that serves as a form of energy storage in animals and fungi.

Cellulose is a polysaccharide made of glucose units linked through 1,4-β glycoside bonds. Glucose is made from carbon dioxide by the chlorophyll contained in plants. The glucose units are polymerized by means of 1,4-β linkages into cellulose as structural materials to physically support the plant against the force of gravity, or the glucose units are polymerized by 1,4-α linkages into amylose (starch). Thus, cellulose and amylose are natural renewable resources and the supply is not dependent upon petroleum.

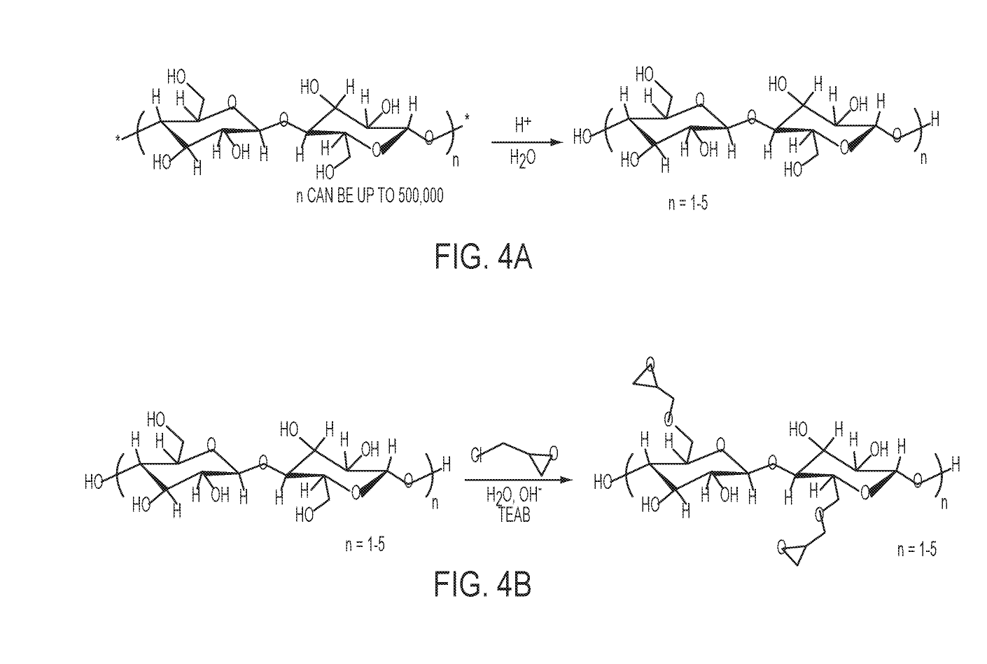

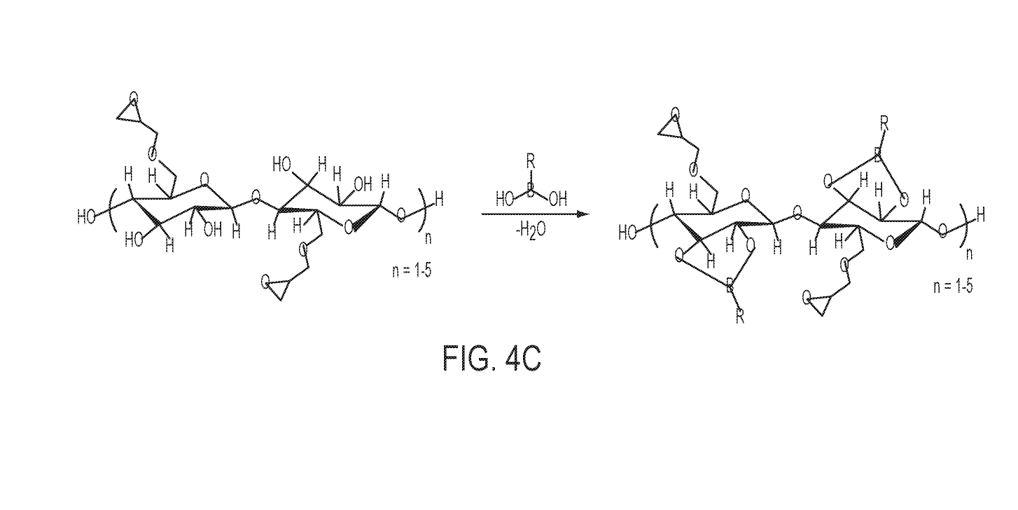

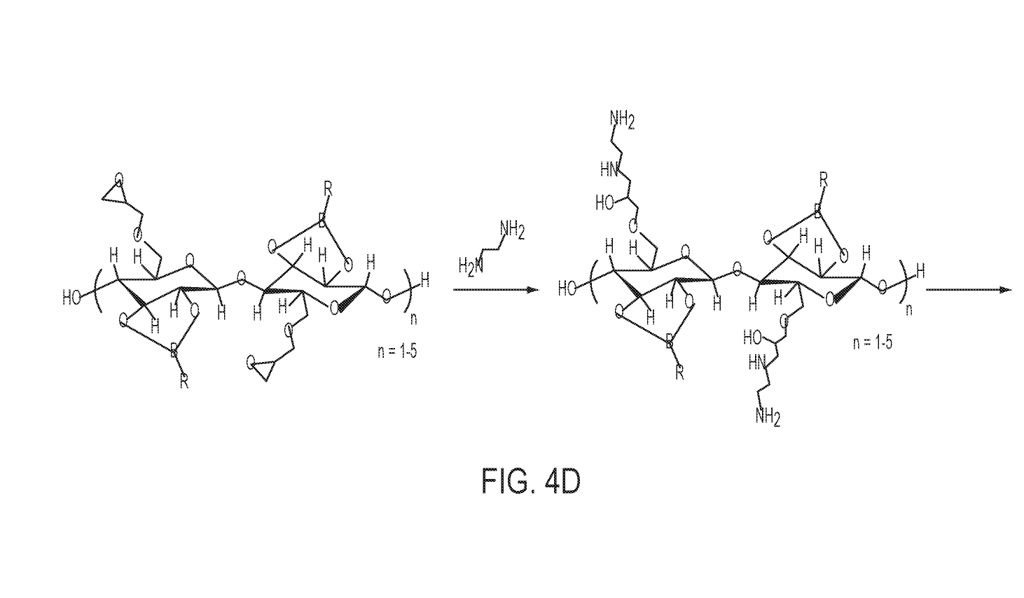

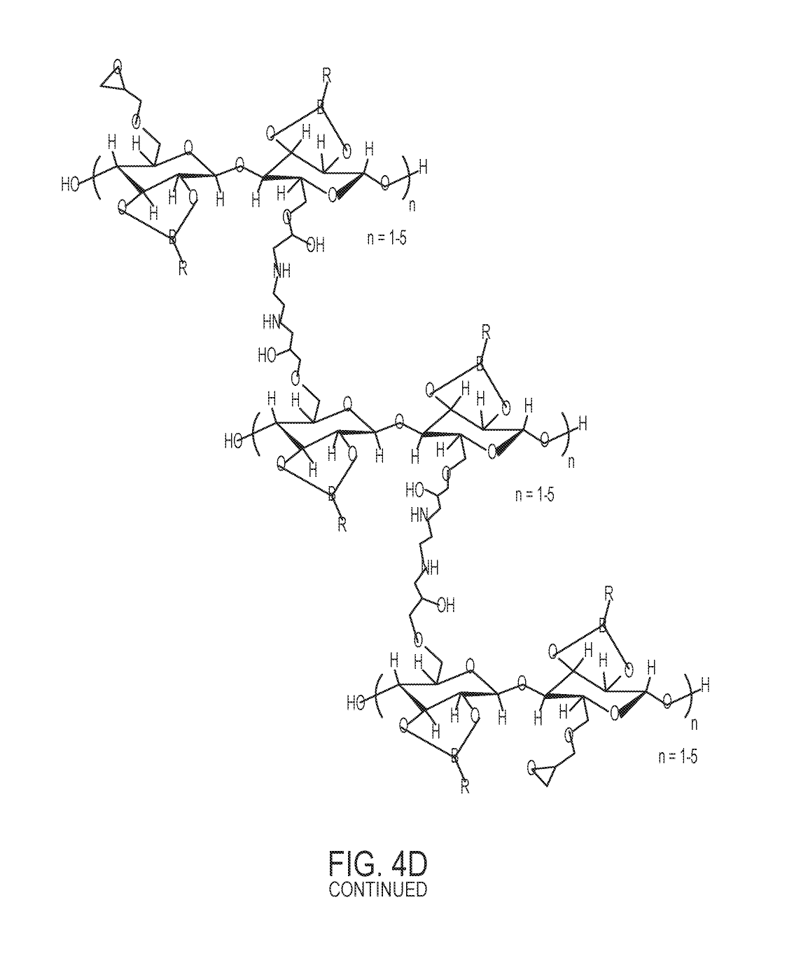

Polysaccharides may be considered as pseudo thermoset polymers in their native form as the extensive hydrogen bonding between the polymer chains prevent melting and flow. High molecular weight polysaccharides would therefore typically be solid as a final product. Therefore, according to an embodiment as presented herein, polysaccharides may be hydrolyzed, or broken down into low molecular weight oligomers of 1 to about 10 monomer units. As an example, cellulose may be broken down into oligomers of glucose having about 2 to about 10 glucose units, or about 1 to about 5 of repeating dimer units (see FIG. 4A). Oligosaccharides may be usable as a resin material since the final product may be in a liquid state. Oligosaccharides may include mono-saccharides, such as glucose, galactose, fructose; di-saccharides, such as maltose, sucrose and lactose; or any saccharides having 1, 2, 3, 4, 5, 6, 7, 8, 9, or 10 monomer units. In an embodiment, polyols (sugar alcohols) may also be used as the saccharide material. Some specific examples of polyols, may include, glycerol, erythritol, xylitol, sorbitol, or combinations thereof.

The oligosaccharides derived from any one, or a combination of the above polysaccharides, may be functionalized to give the oligosaccharides fire retardant properties and provide the ability for the oligosaccharides to be cross-linked to produce a final solid product. Some examples of compounds that may provide fire-retardant properties to the oligosaccharides include, but are not limited to, chlorine-containing hydrocarbons, bromine-containing hydrocarbons, boron compounds, metal oxides, antimony oxides, aluminum hydroxides, molybdenum compounds, zinc oxides, magnesium oxides, organic phosphates, phosphinates, phosphites, phosphonates, phosphenes, halogenated phosphorus compounds, inorganic phosphorus containing salts, nitrogen-containing compounds, or any combination thereof.

In an embodiment, the flame retardant may include at least one organoboryl substituent. The at least one organoboryl substituent may include at least one boronic acid derivative covalently bonded with the oligosaccharide by at least one —B—O-oligosaccharide linkage. As examples, the boronic acid derivative may be an alkyl boronic acid, an alkenyl boronic acid, an aryl boronic acid, a heteroaryl boronic acid, or any combination thereof.

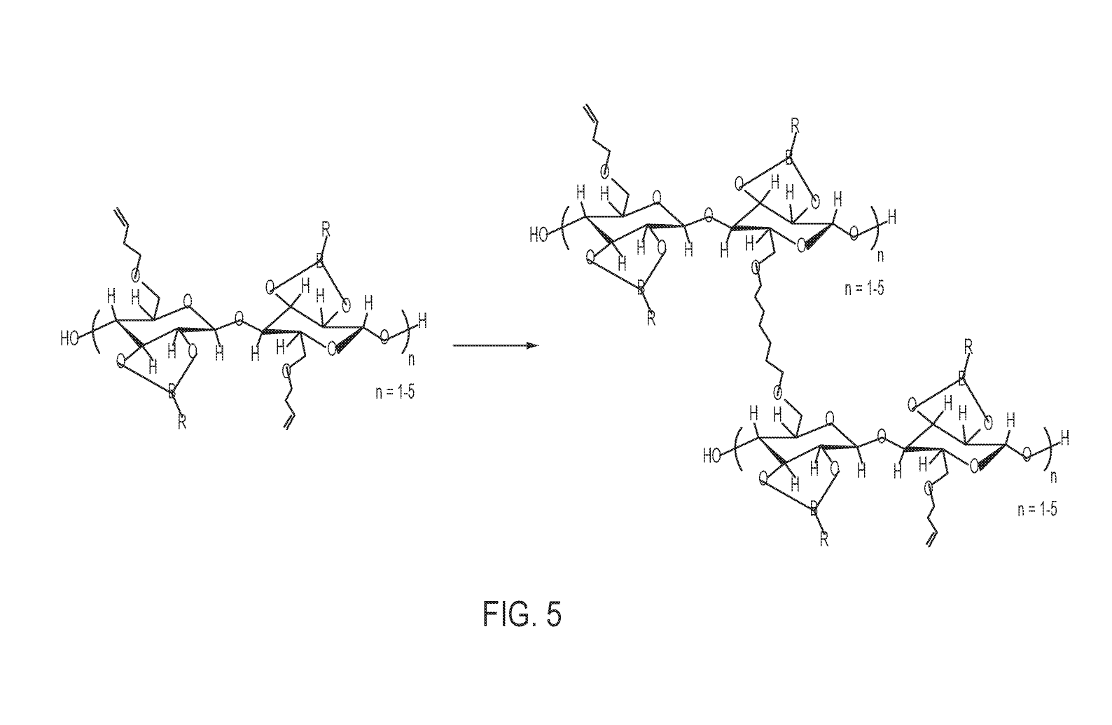

In an embodiment, a functionalized oligosaccharide may include at least one cross-linkable moiety that may be cross-linked with at least one cross-linkable moiety of another functionalized oligosaccharide. Some cross-linkable moieties, such as vinyls as represented in FIG. 5, may directly cross-link with one another so that a vinyl of one functionalized oligosaccharide may directly bond with a vinyl of another functionalized oligosaccharide. Other cross-linkable moieties, such as epoxy as represented in FIG. 4D, may be cross-linked by a cross-linking agent. The at least one cross-linkable moiety and the cross-linking agent may independently be cross-linkable members of the group consisting of acetoacetoxy, imines, acids, anhydrides, amines, amides, epoxies, hydroxyls, blocked isocyanates, isothiocyanates, vinyls, and any combinations thereof. Some examples of paired cross-linkable moieties and cross-linking agents may include, epoxies/amines, epoxies/acids, epoxies/anhydrides, epoxies/hydroxyls (phenols, alcohols, thiols), acetoacetoxy/imines, and blocked isocyanates/amines.

The functionalized oligosaccharides may be used as fibers or as a resin. For example, the fiber in paper products may be lightly borated to maintain the fiber structure. Alternatively, the polymer may be highly borated to render the polymer into a thermoplastic material. The borated cellulose fibers and resins may be fabricated into printed circuit boards using layering processes.

In an embodiment of a printed circuit board assembly, the functionalized oligosaccharides may be oligomer derivatives of cellulose having about 2 to about 6 saccharide units. In a further embodiment, a plurality of the saccharide units may have at least one organoboryl substituent as the flame retardant material. In another embodiment, each oligosaccharide may have at least one cross-linkable moiety that is cross-linked with at least one cross-linkable moiety of another functionalized oligosaccharide by a cross-linking agent. As an example, the at least one cross-linkable moiety may be an epoxy, and the cross-linking agent may be a polyfunctional component selected from amities, amides, phenols, aldehydes, formaldehyde, alcohols, mercaptans, phosphine, melamine, melamine-formaldehyde, carboxylic acids, thiocarboxylic acids, dithiocarboxylic acids, proteins, polypeptides, DNA, selenols, arsines, and maleic systems, or any combination thereof. Examples of the number of saccharide units include 2, 3, 4, 5, and 6.

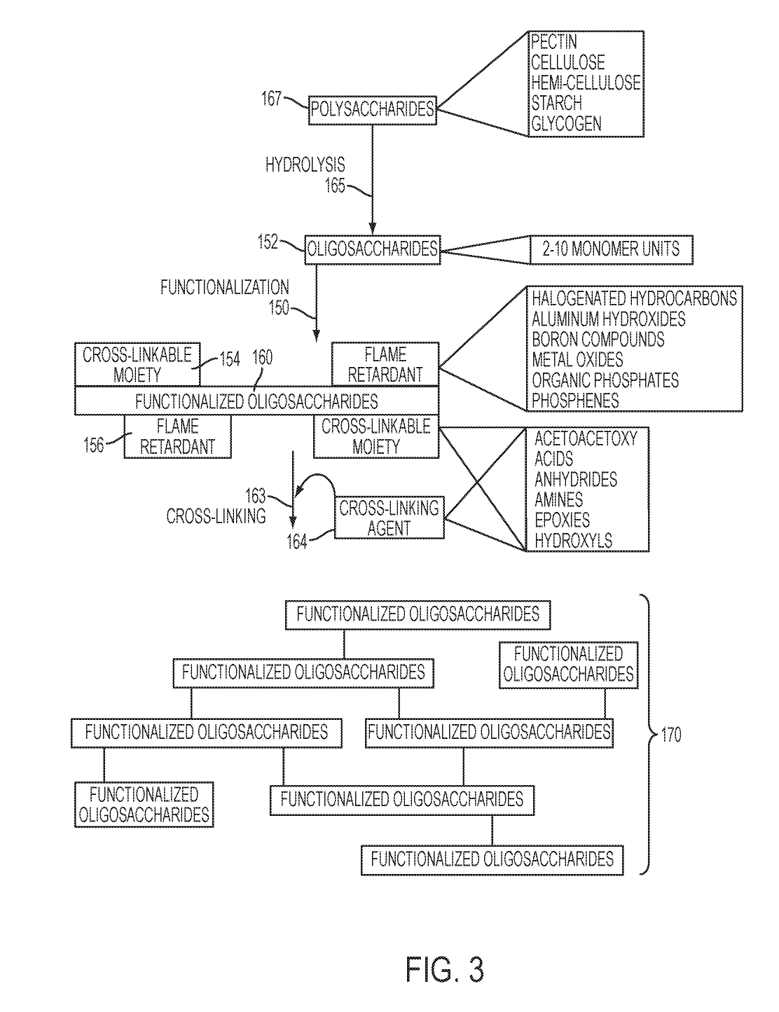

In an embodiment, a flame resistant material may include cross-linked oligosaccharides functionalized with a flame retardant. The flame retardant, cross-linking moieties and oligosaccharides may be selected from any of the variants as discussed above. The material may be produced in a manner, for example, as represented in FIG. 3, wherein the method includes a functionalizing step 150 wherein the oligosaccharides 152 are chemically modified to include components that make the oligosaccharides cross-linkable and also give the oligosaccharides flame retardant properties. Oligosaccharides 152 may be functionalized with cross-linkable moieties 154 and a flame retardant 156 to produce functionalized oligosaccharides 160. The functionalized oligosaccharides 160 may be cross-linked 163 with a cross-linking agent 164.

In an embodiment, the oligosaccharides 152 may have about 1 to about 10 monomer units. The oligosaccharides 152 may be produced by hydrolyzing 165 polysaccharides 167 selected from the group consisting of pectin, cellulose, hemi-cellulose, starch, glycogen, amylose, and any combinations thereof. Examples of the number of monomer units include 1, 2, 3, 4, 5, 6, 7, 8, 9, and 10.

The functionalizing step 150 may include functionalizing the oligosaccharides 152 with a flame retardant 156 by covalently bonding the flame retardant to the oligosaccharides. The flame retardant may be selected from the group consisting of chlorine-containing hydrocarbons, bromine-containing hydrocarbons, boron compounds, metal oxides, antimony oxides, aluminum hydroxides, molybdenum compounds, zinc oxides, magnesium oxides, organic phosphates, phosphinates, phosphites, phosphonates, phosphenes, halogenated phosphorus compounds, inorganic phosphorus containing salts, nitrogen-containing compounds, or any combination thereof.

In an embodiment, the oligosaccharides 152 may be functionalized with at least one organoboryl substituent as the flame retardant 156. The functionalizing may include covalently bonding at least one boronic acid derivative with the oligosaccharide by at least one —B—O-oligosaccharide linkage.

In an embodiment, the oligosaccharides 152 may be functionalized with at least one cross-linkable moiety 154 by covalently bonding the cross-linkable moieties to the oligosaccharides 152. The cross-linkable moieties 154 may be selected from the group consisting of acetoacetoxy, acids, anhydrides, amines, amides, epoxies, hydroxyls, blocked isocyanates, isothiocyanates, vinyls, and any combinations thereof. The cross-linking agent 164 may be selected to cross-link with the cross-linkable moieties 154 and may be another component of the group consisting of acetoacetoxy, acids, anhydrides, amines, amides, epoxies, hydroxyls, blocked isocyanates, isothiocyanates, vinyls, and any combinations thereof. The cross-linkable moieties 154 and the cross-linking agent 164 may be selected so that the cross-linking agent covalently bonds with a cross-linkable moiety of one functionalized oligosaccharide and a cross-linkable moiety of another functionalized oligosaccharide to link the oligosaccharides together and thereby form a solidified fire resistant material 170.

The materials for producing the flame resistant material may be provided in a kit form. Such a kit may include liquid components that may be mixed on site by the end user to initiate the cross-linking reaction. A kit may include a first component of oligosaccharides functionalized with a flame retardant, and having cross-linkable moieties configured to be cross-linkable with cross-linkable moieties of at least one other of the functionalized oligosaccharides. The kit may also include at least one cross-linking agent for cross-linking the cross-linkable moieties.

In an embodiment, the cross-linkable moieties 154 may be an epoxy, and the cross-linking agent 164 may be a polyfunctional component selected from the group consisting of acetoacetoxy, acids, anhydrides, amines, amides, epoxies, hydroxyls, blocked isocyanates, isothiocyanates, vinyls, and any combinations thereof.

### EXAMPLES

### Example 1

### A Boronated Epoxy-Oligocellulose Material

Boronated epoxy-cellulose hybrids may be mixtures of low molecular weight oligocellulose species. Cellulose polymers, such as cellulose from trees, may have thousands of monomer units and molecular weights in the millions. Oligomers of the cellulose may be produced that have only 2-6 monomer units (1-3 repeat units) as shown in FIG. 4A. As described in Example 2, the oligocellulose is functionalized with a cross-linkable epoxy group, and a fire retardant boronic acid group to produce a boronated epoxy-oligocellulose material in a liquid state.

### Example 2

### Production of Boronated Epoxy-Oligocellulose

As depicted in FIG. 4A, cellulose is broken down into short oligomer chains having 2-6 monomer units (1-3 repeat units). This cleaving of the cellulose is performed under acidic conditions with water.

As depicted in FIG. 4B, the oligocellulose material from FIG. 4A is reacted with epichlorohydrin to impart epoxy functional moieties to the oligocellulose materials. This functionalizing step is performed in water. The oligocellulose materials are dissolved in water, and hydroxide and tetrabutylammonium bromide phase transfer catalyst are added to the aqueous solution. Epichlorohydrin is added slowly (for example, dropwise) to the mixture. The mixture is heated to about 60° C. and allowed to stir for five hours. Water is removed by lyophilyzation, and the mixture is purified by removing any impurities with acetone.

The boronation of the epoxy-functionalized oligocellulose is depicted in FIG. 4C. The functionalized cellulose fiber or particles are suspended in toluene. Organoboronic acid is added to the toluene in the ratio of 1 part cellulose to 5 parts boronic acid. A small amount of PTSA catalyst (para-toluenesulfonic acid) is added. The system is refluxed and the water collected in a Dean-Stark trap (the volume of collected water may be used as an indicator of the reaction progress). In the remaining steps, the acid is neutralized and separated from the reaction mixture, followed by removal of the toluene, leaving oligocellulose that is now functionalized by both the cross-linkable epoxy and the fire-retardant boronic acid.

### Example 3

### Kit For a Flame Resistant Material

The boronated epoxy-oligocellulose material of Example 2 is produced in a liquid state, and is packaged in an appropriate container as a first component of a kit. To provide for an end-use cross-linking of the functionalized material, a polyfunctional amine, such as ethylenediamine, is provided in a second container as a second component of the kit. An end-user may then cross-link the functionalized oligocellulose, as shown in FIG. 4D, by mixing the functionalized oligocellulose with the diamine.

### Example 4

### Printed Circuit Board Assemblies

PCBs may be produced using the cross-linkable oligosaccharides in a manner as represented in FIG. 1. A boronated epoxy-cellulose material is used in the PCB construction. Cotton fiber paper 100, is used as a substrate material for the PCBs. A substrate sheet 110 is produced by saturating the paper 100 with the boronated epoxy-cellulose hybrid resin and either a blocked curing agent or a slow curing agent. The resin is partially cured to provide some physical properties (such as rigidity) to the sheet 110. Copper traces 115 are printed onto the epoxy-cellulose infused paper 110 to provide conductive pathway sheet 120 for the final product. Various layers of conductive pathway sheets 120-1, 120-2 . . . 120-n are stacked together and the system is heated to an elevated temperature to fuse the sheets together and completely cure the epoxy resin to form a printed circuit board 130. Processor chips, diodes, and other components 135 are attached into place, such as by soldering, to form a finished PCB assembly 140.

### Example 5

### Comparison of Printed Circuit Boards

Electronic circuits of PCBs are extremely sensitive to ionic conditions and galvanic corrosion. Boric acid mixtures with various components are usable as flame retardants, but boric acid is not suitable for use in conjunction with printed circuit boards as boric acid causes ionic conditions that lead to corrosion. Conventional PCBs that use brominated-BPA epoxy resins may reduce fire events, but these resins may not be able to sustain suppression of combustion throughout a duration of the fire event. In addition, brominated-BPA can also behave as an endocrine toxin and releases toxic chemicals when pyrolyzed or decomposed.

PCBs produced using functionalized oligosaccharides, for example functionalized cellulose materials, as described in the disclosed embodiments and in the Examples, are completely non-ionic, and may be made with organoboron compounds and cellulose. The functionalized oligosaccharides, for example borated cellulose materials, as described in the disclosed embodiments and in the Examples, are configured to minimize, and possibly eliminate, ionic conditions, and will also minimize, and possibly eliminate corrosion of sensitive electronic parts.

As mentioned above, a challenge with the multitude of electronic equipment and consumer products now available is the rapid accumulation of waste. Currently there is no effective or efficient means of dealing with the waste generated from conventional printed circuit boards. The accumulation of waste is rapidly growing with the ever shortening life cycle of products. The materials currently used in the construction of PCBs make it difficult to recycle and treat the waste. One of those materials, brominated BPA is difficult to combust or incinerate, and, as discussed above, pyrolysis yields toxic gasses. Much of the waste generated is shipped to third world nations where it may be burned in fire pits, exposing those in the vicinity to toxic gasses and chemicals from the decomposition of the waste, while putting a large amount of pollution into the atmosphere.

In contrast, printed circuit boards produced with functionalized oligosaccharides, for example functionalized cellulose materials as described in the disclosed embodiments and in the Examples, are made of natural products and can be decomposed with bacteria that feed upon boron and cellulose. The use of natural materials allows for composting when dealing with waste from electronic products that incorporate such materials. In such a scenario, the metals would still need to be collected, but the PCB materials made of cellulose, as described in the disclosed embodiments and in the Examples, may then be composted. The materials should also remain stable under normal operating conditions of the electronic equipment, but, may also be hydrolyzed back to cellulose and the boron compounds, to recycle and reuse the materials, thus, reducing electronic wastes.

This disclosure is not limited to the particular systems, devices and methods described, as these may vary. The terminology used in the description is for the purpose of describing the particular versions or embodiments only, and is not intended to limit the scope.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A printed circuit board assembly comprising:
at least one substrate sheet comprising a flame resistant material, the flame resistant material comprising functionalized oligosaccharides, the functionalized oligosaccharides comprising cross-linked oligosaccharides functionalized with a flame retardant;
electrical conduction traces disposed on the substrate sheet; and
electronic components disposed on the substrate sheet in contact with the electrical conduction traces.

2. The printed circuit board assembly of claim 1, wherein the electronic components comprise at least one of: microprocessors, diodes, capacitors, resistors, electronic filters, microcontrollers, integrated circuits, and logic devices.

3. The printed circuit board assembly of claim 1, wherein the substrate sheet comprises fibrous paper infused with the flame resistant material.

4. (canceled)

5. The printed circuit board assembly of claim 1, wherein the flame retardant is selected from the group consisting of chlorine-containing hydrocarbons, bromine-containing hydrocarbons, boron compounds, metal oxides, antimony oxides, aluminum hydroxides, molybdenum compounds, zinc oxides, magnesium oxides, organic phosphates, phosphinates, phosphites, phosphonates, phosphenes, halogenated phosphorus compounds, inorganic phosphorus containing salts and nitrogen-containing compounds.

6. The printed circuit board assembly of claim 1, wherein the flame retardant comprises at least one organoboryl substituent.

7. The printed circuit board assembly of claim 1, wherein the flame retardant includes at least one organoboryl substituent having at least one boronic acid derivative covalently bonded with the oligosaccharide by at least one —B—O-oligosaccharide linkage, wherein B is boron and O is oxygen.

8. The printed circuit board assembly of claim 7, wherein the boronic acid derivative is an alkyl boronic acid, an alkenyl boronic acid, an aryl boronic acid, a heteroaryl boronic acid, or any combination thereof.

9. The printed circuit board assembly of claim 1, wherein the functionalized oligosaccharides comprise at least one of monosaccharides, disaccharides, polyols, and oligomer derivatives of a polysaccharide selected from the group consisting of pectin, cellulose, hemi-cellulose, starch, glycogen, amylose, and any combinations thereof.

10. The printed circuit board assembly of claim 1, wherein each functionalized oligosaccharide comprises at least one of:
at least one cross-linkable moiety that is cross-linked with at least one cross-linkable moiety of another functionalized oligosaccharide by a cross-linking agent; and
at least one cross-linkable moiety that is directly bonded with at least one cross-linkable moiety of another functionalized oligosaccharide, wherein
the at least one cross-linkable moiety and the cross-linking agent are cross-linkable members selected from the group consisting of acetoacetoxy, acids, anhydrides, amines, amides, epoxies, hydroxyls, blocked isocyanates and isothiocyanates, vinyls.

11-13. (canceled)

14. A flame resistant material comprising:
functionalized oligosaccharides including cross-linked oligosaccharides functionalized with a flame retardant.

15. The flame resistant material of claim 14, wherein the functionalized oligosaccharides comprise about 1 to about 10 saccharide units.

16. The flame resistant material of claim 14, wherein the flame retardant is selected from the group consisting of chlorine-containing hydrocarbons, bromine-containing hydrocarbons, boron compounds, metal oxides, antimony oxides, aluminum hydroxides, molybdenum compounds, zinc oxides, magnesium oxides, organic phosphates, phosphinates, phosphites, phosphonates, phosphenes, halogenated phosphorus compounds, inorganic phosphorus containing salts and nitrogen-containing compounds.

17. The flame resistant material of claim 14, wherein the flame retardant is a boron compound.

18. The flame resistant material of claim 14, wherein the flame retardant comprises at least one organoboryl substituent.

19. The flame resistant material of claim 1, wherein the flame retardant includes at least one organoboryl substituent having at least one boronic acid derivative covalently bonded with the oligosaccharide by at least one —B—O-oligosaccharide linkage

20. The flame resistant material of claim 19, wherein the boronic acid derivative is an alkyl boronic acid, an alkenyl boronic acid, an aryl boronic acid, a heteroaryl boronic acid, or a combination thereof.

21. (canceled)

22. The flame resistant material of claim 14, wherein the functionalized oligosaccharides are selected from the group consisting of pectin, cellulose, hemi-cellulose, starch, glycogen and amylose.

23-34. (canceled)

35. A method for producing a flame resistant material, the method comprising:
functionalizing oligosaccharides with cross-linkable moieties and a flame retardant; and
cross-linking the functionalized oligosaccharides.

36. The method of claim 35, wherein the functionalizing comprises functionalizing the oligosaccharides having from about 1 to about 10 saccharide units.

37. The method of claim 35, further comprising producing the oligosaccharides by hydrolyzing polysaccharides selected from the group consisting of pectin, cellulose, hemi-cellulose, starch, glycogen and amylose.

38. The method of claim 35, wherein the functionalizing with a flame retardant comprises covalently bonding the flame retardant to the oligosaccharides, wherein the flame retardant is selected from the group consisting of chlorine-containing hydrocarbons, bromine-containing hydrocarbons, boron compounds, metal oxides, antimony oxides, aluminum hydroxides, molybdenum compounds, zinc oxides, magnesium oxides, organic phosphates, phosphinates, phosphites, phosphonates, phosphenes, halogenated phosphorus compounds, inorganic phosphorus containing salts and nitrogen-containing compounds.

39. The method of claim 35, wherein the functionalizing comprises functionalizing with a flame retardant comprising at least one organoboryl substituent.

40. The method of claim 35, wherein the functionalizing with a flame retardant comprises covalently bonding at least one boronic acid derivative with the oligosaccharide by at least one —B—O-oligosaccharide linkage.

41. The method of claim 35, wherein the functionalizing with cross-linkable moieties comprises covalently bonding cross-linkable moieties to the oligosaccharides, wherein the cross-linkable moieties are selected from the group consisting of acetoacetoxy, acids, anhydrides, amines, amides, epoxies, hydroxyls, blocked isocyanates and isothiocyanates, vinyls.

42. The method of claim 35, wherein the cross-linking comprises cross-linking with a cross-linking agent selected to cross-link with the cross-linkable moieties, and the cross-linking agent being selected from the group consisting of acetoacetoxy, acids, anhydrides, amines, amides, epoxies, hydroxyls, blocked isocyanates and isothiocyanates, vinyls.

43. The method of claim 35, wherein the functionalizing comprises functionalizing with cross-linkable moieties including epoxies.

44. The method of claim 35, wherein the cross-linking comprises cross-linking with a cross-linking agent, and the cross-linking agent having a polyfunctional component selected from the group consisting of amines, amides, phenols, aldehydes, formaldehyde, alcohols, mercaptans, phosphine, melamine, melamine-formaldehyde, carboxylic acids, thiocarboxylic acids, dithiocarboxylic acids, proteins, polypeptides, DNA,
selenols, arsines, and maleic systems.

45. The method of claim 35, further comprising:
producing the oligosaccharides by hydrolyzing cellulose into cellulose oligomers having from about 2 to about 6 saccharide units.

46. The method of claim 35, wherein
functionalizing the oligosaccharides comprises:
covalently bonding epoxies to the cellulose oligomers to produce epoxy-cellulose oligomers;
reacting the epoxy-cellulose oligomers with an organo-boronic acid to produce a cross-linkable flame resistant component; and
cross-linking comprises mixing the cross-linkable flame resistant component with a cross-linking agent comprising a polyfunctional component selected from the group consisting of amines, phenols, alcohols, mercaptans, phosphine, melamine formaldehyde, selenols, arsines, and maleic systems.
